(19) United States
(12) Patent Application Publication
(10) Pub. No.: US 2012/0094430 A1
(43) Pub. Date: Apr. 19, 2012

(54) CRYSTALLINE SILICON MANUFACTURING APPARATUS AND METHOD OF MANUFACTURING SOLAR CELL USING THE SAME

(75) Inventor: Seung-Jae JUNG, Seoul (KR)

(73) Assignee: SAMSUNG ELECTRONICS CO., LTD., Suwon-si (KR)

(21) Appl. No.: 13/117,465

(22) Filed: May 27, 2011

(30) Foreign Application Priority Data
Oct. 19, 2010 (KR) 10-2010-0101850

(51) Int. Cl. H01L 31/18; C23C 16/48

(52) U.S. Cl. 438/97; 118/723 R; 257/E31.043

(57) ABSTRACT

A method of manufacturing a solar cell includes: forming a first electrode on a substrate; forming a P-type layer on the first electrode; forming an N-type layer on the P-type layer using a crystalline silicon manufacturing apparatus; and forming a second electrode on the N-type layer to form the solar cell. In this method, the forming of the N-type layer includes contacting the P-type layer with a gas including monosilane and hydrogen to form a sub N-type layer including an amorphous silicon layer, mirco-crystallizing the amorphous silicon layer by irradiating light onto the amorphous silicon layer, and repeating the contacting and the mirco-crystallizing to form the N-type layer.

### CROSS-REFERENCE TO RELATED APPLICATION

This application claims priority to Korean Patent Application No. 10-2010-0101850, filed on Oct. 19, 2010, and all the benefits accruing therefrom under 35 U.S.C. §119, the content of which in its entirety, is herein incorporated by reference.

### BACKGROUND OF THE INVENTION

(a) Field of the Invention

The present disclosure relates to a crystalline silicon manufacturing apparatus and a method of manufacturing a solar cell using the same.

(b) Description of the Related Art

Solar cells convert solar energy into electrical energy. Solar cells are basically PN junction diodes and may be classified according to materials used for light absorbing layers of the solar cells.

Solar cells using a light absorbing layer including silicon include crystalline wafer type solar cells, which may include single-crystalline or polycrystalline silicon light absorbing layer, and thin film type solar cells, which may include a crystalline or amorphous silicon light absorbing layer.

Amorphous silicon, which may be used for a light absorbing layer of a solar cell, has a light absorption coefficient which is larger than a light absorption coefficient of crystalline silicon, and thus is capable of absorbing a larger amount of light with a smaller thickness. However, because the amorphous silicon has many disadvantages and exhibits light induced degradation, it is difficult to manufacture high-efficiency solar cells using amorphous silicon.

However, because micro-crystalline silicon has a light absorption coefficient which is larger than that of polycrystalline or single-crystalline silicon, and has fewer disadvantages than amorphous silicon and does not exhibit light induced degradation, micro-crystalline silicon is regarded as a promising material for a light absorbing layer for a high-efficiency thin film type solar cell.

Methods of forming micro-crystalline silicon include direct formation methods, such as plasma-enhanced chemical vapor deposition (“PECVD”), hot-wire chemical vapor deposition (“CVD”), and forming mirco-crystalline silicon by forming amorphous silicon and then performing a crystallization process. In the case of direct formation methods, because the speed of deposition for obtaining a high-quality thin film is low, mass production using direct formation is difficult. Also, crystallization of amorphous silicon has disadvantages because a process temperature is limited by a material of a substrate and it is difficult to crystallize a thin silicon film having a thickness of several micrometers. According there remains a need for an improved method for forming a micro-crystalline silicon layer.

### BRIEF SUMMARY OF THE INVENTION

Disclosed is a method which includes forming a high-quality micro-crystalline silicon layer by forming amorphous silicon and post crystallizing consecutively and repeatedly using a crystalline silicon manufacturing apparatus which includes both a hot-wire CVD apparatus and a post crystallization apparatus. The disclosed method and apparatus solve the problem of how to directly form micro-crystalline silicon and how to form micro-crystalline silicon using post crystallization.

An embodiment provides a method of manufacturing a solar cell, the method including: forming a first electrode on a substrate; forming a P-type layer on the first electrode; forming an N-type layer on the P-type layer using a crystalline silicon manufacturing apparatus; and forming a second electrode on the N-type layer to form the solar cell, wherein the forming of the N-type layer includes contacting the P-type layer with a gas including monosilane and hydrogen to form a sub N-type layer including an amorphous silicon layer, micro-crystallizing the amorphous silicon layer by irradiating light onto the amorphous silicon layer, and repeating the contacting and the micro-crystallizing to form the N-type layer.

A thickness of each sub N-type layer may independently be about 0.1 to about 0.5 micrometer.

A thickness of the N-type layer may be about 1 to about 20 micrometers.

A thickness of the P-type layer may be about 0.1 to about 0.5 micrometer.

The crystalline silicon manufacturing apparatus may include a body, a gas inlet which is fluidly connected to the body, a plurality of gas jetting units, which jet the gas, at least one hot wire, which is separated from each gas jetting unit of the plurality of the gas jetting units and which decomposes or activates the jetted gas, and a plurality of lamp units, wherein each lamp unit of the plurality of lamp units is disposed between respective gas jetting units of the plurality of gas jetting units, and wherein each lamp unit of the plurality of lamp units irradiates light onto the amorphous silicon layer.

The at least one hot wire may be disposed only at a portion corresponding to the gas jetting units.

Each lamp unit of the plurality of lamp units may include a lamp, which emits light, a reflective film, which reflects the emitted light, and a cover, which protects the lamp and the reflective film, and the method of manufacturing the solar cell may further include: removing the cover, and then irradiating light onto the amorphous silicon layer.

Another embodiment provides a method of manufacturing a solar cell, including: forming a first electrode on a substrate; forming an N-type layer on the first electrode; forming a P-type layer on the N-type layer using a crystalline silicon manufacturing apparatus; and forming a second electrode on the P-type layer to form the solar cell, wherein the forming of the P-type layer includes contacting the N-type layer with a gas including monosilane and hydrogen to form a sub P-type layer including an amorphous silicon layer, mirco-crystallizing the amorphous silicon layer by irradiating light onto the amorphous silicon layer, and repeating the contacting and the mirco-crystallizing to form the P-type layer.

A thickness of each sub P-type layer may independently be about 0.1 to about 0.5 micrometer.

A thickness of the P-type layer may be about 1 to about 20 micrometers.

A thickness of the N-type layer may be about 0.1 to about 0.5 micrometer.

Another embodiment provides a crystalline silicon manufacturing apparatus including: a body; a gas inlet, which is fluidly connected to the body; a plurality of gas jetting units, which jet a gas including monosilane and hydrogen; at least one hot wire, which is separated from each gas jetting unit of the plurality of gas jetting units and which decomposes or activates the jetted gas; and a plurality of lamp units, wherein each lamp unit of the plurality of lamp units is disposed between respective gas jetting units of the plurality of gas jetting units and wherein each lamp unit of the plurality of lamp units irradiates light.

The at least one hot wire may be disposed only at a portion corresponding to the gas jetting units.

Each lamp unit of the plurality of lamp units may include a lamp, which emits light, a reflective film, which reflects the emitted light, and a cover, which protects the lamp and the reflective film.

The body may include a diffusion unit diffusing the gas.

According to an embodiment, a gas of monosilane SiH₄ and hydrogen H₂ can be decomposed or activated with a hot wire to form an amorphous silicon layer, and then light can be irradiated onto the amorphous silicon layer to crystallize the amorphous silicon layer, thereby forming a high-quality mirco-crystalline silicon layer. Further, it is possible to solve or avoid problems of substrate deformation and impurity diffusion by repeatedly forming thin mirco-crystalline silicon layers.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view of an embodiment of a solar cell;

FIG. 2 is a cross-sectional view of an embodiment of a crystalline silicon manufacturing apparatus;

FIG. 3 is a rear view of the crystalline silicon manufacturing apparatus of FIG. 2;

FIGS. 4 to 7 are views sequentially showing an embodiment of a method of manufacturing a solar cell;

FIG. 8 is a cross-sectional view of an embodiment of a solar cell; and

FIGS. 9 to 12 are views sequentially showing an embodiment of a method of manufacturing a solar cell.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer or section. Thus, “a first element,” “component,” “region,” “layer,” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

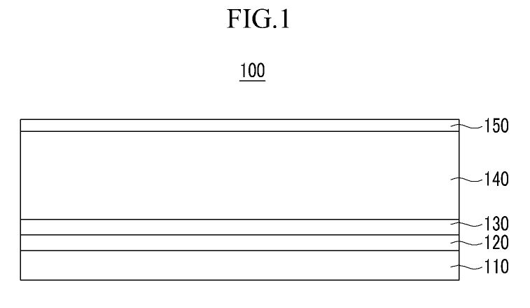

FIG. 1 is a cross-sectional view of an embodiment a solar cell.

As shown in FIG. 1, a solar cell 100 according to an exemplary embodiment includes a first electrode 120 disposed on a substrate 110. The first electrode 120 comprises a reflective conductive metal, such as molybdenum (Mo), aluminum (Al), or copper (Cu). Also, the first electrode 120 may comprise a transparent conductive metal, such as ZnO, indium tin oxide (“ITO”), or indium zinc oxide (“IZO”). A combination comprising at least one of the foregoing can be used.

On the first electrode 120, a P-type layer 130 and an N-type layer 140 are sequentially disposed.

The P-type layer 130 may be formed by doping amorphous silicon with a P-type impurity, such as boron (B) or aluminum (Al), and the P-type layer 130 may have a thickness of about 0.1 to about 10 micrometers (μm), specifically about 0.2 to about 5 μm, more specifically about 0.5 to about 1 μm. The N-type layer 140 may be formed by doping mirco-crystalline silicon with an N-type impurity, such as phosphorus (P), and may have a thickness of about 0.1 to about 40 μm, specifically about 1 to about 20 μm, more specifically about 2 to about 10 μm. In an embodiment, the N-type layer 140 may be a light absorbing layer.

On the N-type layer 140, a second electrode 150 is disposed (e.g., formed). The second electrode 150 may comprise a transparent conductive metal such as ZnO, ITO, or IZO. Also, the second electrode 150 may comprise a reflective conductive metal such as molybdenum (Mo), aluminum (Al), or copper (Cu). A combination comprising at least one of the foregoing can be used.

In an embodiment, if the first electrode 120 comprises a reflective conductive metal, the second electrode 150 may comprise a transparent conductive metal, and if the first electrode 120 comprises a transparent conductive metal, the second electrode 150 may comprise a reflective conductive metal.

As such, the solar cell 100 collects electrons and holes into the N-type layer 140 and the P-type layer 130, respectively, when light (e.g., sunlight) is absorbed in the solar cell 100, thereby generating electric current.

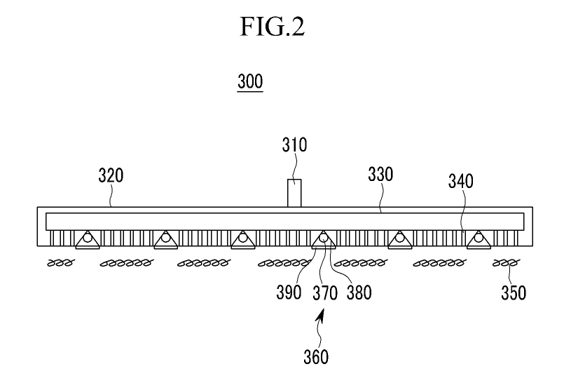

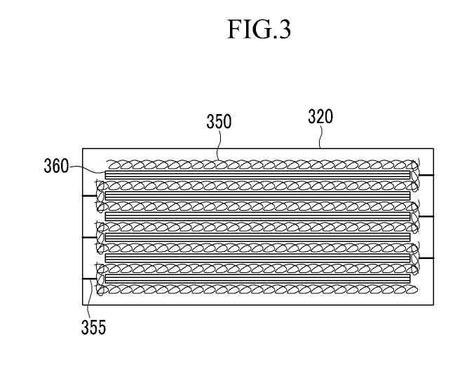

Next, a crystalline silicon manufacturing apparatus according to an exemplary embodiment will be further disclosed with reference to FIGS. 2 and 3.

FIG. 2 is a cross-sectional view of a crystalline silicon manufacturing apparatus according to an exemplary embodiment, and FIG. 3 is a rear view of the crystalline silicon manufacturing apparatus of FIG. 2.

As shown in FIGS. 2 and 3, a crystalline silicon manufacturing apparatus 300 includes a body 320, a gas inlet 310 fluidly connected with the body 320, through which a gas comprising, consisting essentially of, or consisting of monosilane (i.e., SiH₄) and hydrogen (i.e., H₂) is injected into the body 320, gas jetting units 340, which jet the gas, at least one hot wire 350, which decompose or activate the gas jetted from the gas jetting units 340 with heat, and lamp units 360, which emit light between the gas jetting units 340.

A diffusion unit 330, which diffuses the injected gas, is disposed in the body 320, and the lamp units 360 each include a lamp 370, a reflective film 380 for reflecting light, and a cover 390 which protects the lamp 370 and the reflective film 380 from foreign substances.

The at least one hot wire 350 is spaced apart from the gas jetting units 340 by about 0.1 to about 100 μm, specifically about 1 to about 20 μm, more specifically about 2 μm or more, and are fixed to the body 320 by fixing members 355. In an embodiment, the at least one hot wire 350 is positioned only at a portion corresponding to the gas jetting units 340 and is not positioned at portions corresponding to the lamp units 360.

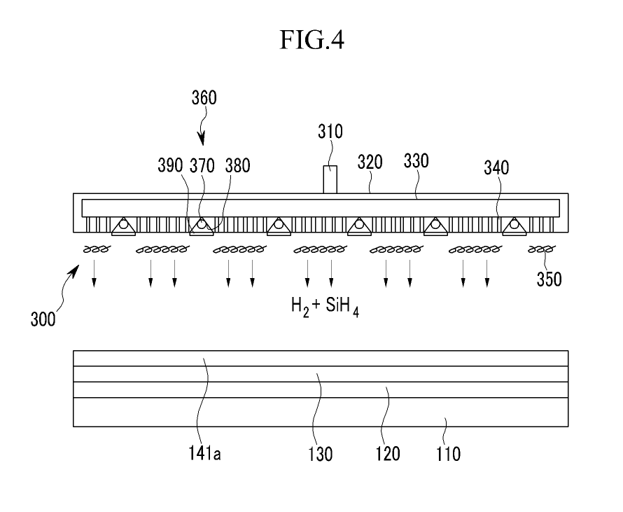

Next, a method of manufacturing a solar cell by using a crystalline silicon manufacturing apparatus according to an exemplary embodiment will be further disclosed with reference to FIGS. 4 to 7.

FIGS. 4 to 7 are views sequentially showing an embodiment of a method of manufacturing a solar cell.

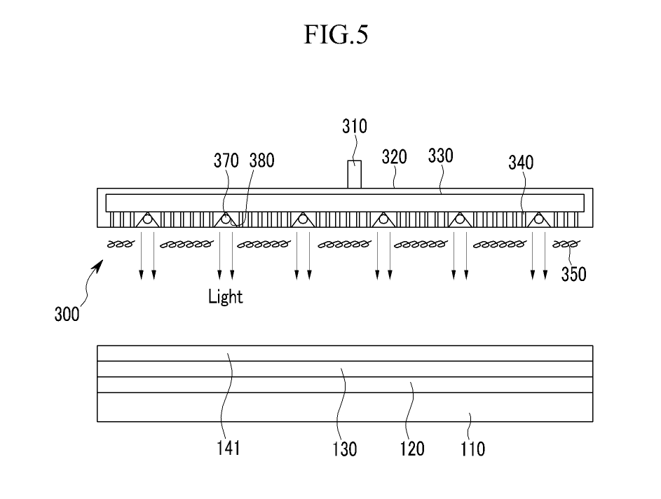

First, as shown in FIGS. 4 and 5, on a substrate 110, a first electrode 120 is disposed (e.g., deposited) by disposing a reflective conductive metal, such as molybdenum (Mo), aluminum (Al), or copper (Cu), and on the first electrode 120, a P-type layer 130 is formed by doping amorphous silicon with a P-type impurity, such as boron (B), or aluminum (Al). A combination comprising at least one of the foregoing can be used. In an embodiment, the P-type layer 130 may have thickness of about 0.01 to about 10 μm, specifically about 0.05 to about 5 μm, more specifically about 0.1 to about 0.5 μm.

Next, a first amorphous silicon layer 141a is formed on the P-type layer 130 by using a crystalline silicon manufacturing apparatus 300. The gas comprising monosilane (SiH₄) and hydrogen (H₂) is injected into the body 320 of the crystalline silicon manufacturing apparatus 300, is diffused by the diffusion unit 330, and is jetted by the gas jetting units 340. The jetted gas is decomposed or activated by the at least one hot wire 350, whereby the first amorphous silicon layer 141a is formed.

Next, the covers 390 of the lamp units 360 are removed and light is irradiated onto the first amorphous silicon layer 141a, whereby the first amorphous silicon layer 141a is crystallized so as to form a first sub N-type layer 141. In an embodiment, the first sub N-type layer 141 may have a thickness of about 0.01 to about 10 μm, specifically about 0.05 to about 5 μm, more specifically about 0.1 to about 0.5 μm.

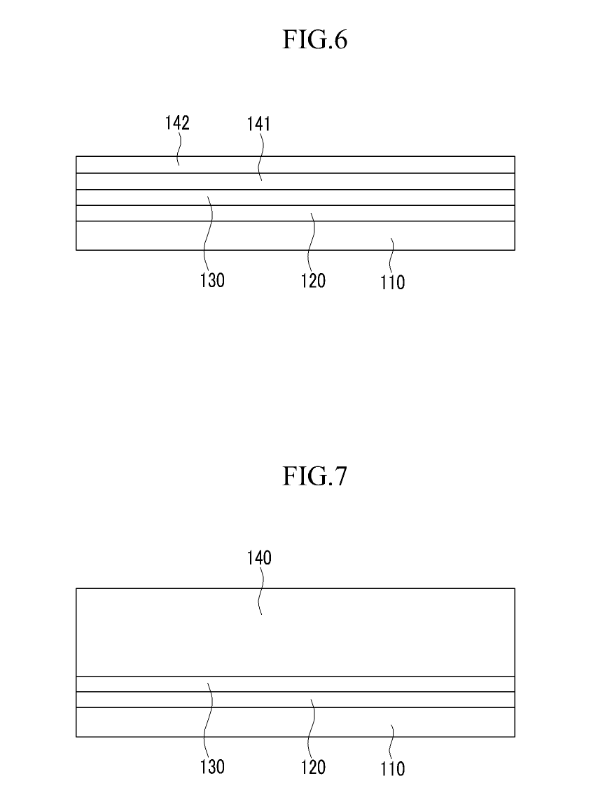

Next, as shown in FIGS. 6 and 7, a second sub N-type layer 142 is formed on the first sub N-type layer 141. The second sub N-type layer 142 is formed by the same method as the method of forming the first sub N-type layer 141. That is, an amorphous silicon layer is formed and crystallized on the first sub N-type layer 141 using the crystalline silicon manufacturing apparatus 300, so as to form the second sub N-type layer 142. The second sub N-type layer 142 may have the same or a different thickness than the first sub N-type layer 141. The second sub N-type layer 142 may have a thickness of about 0.01 to about 10 μm, specifically about 0.05 to about 5 μm, more specifically about 0.1 to 0.5 μm.

Then, an N-type layer 140 is formed on the P-type layer 130 by repeating the mirco-crystalline silicon forming process many times using the crystalline silicon manufacturing apparatus 300. The N-type layer 140 may thus comprise a product of the first sub N-type layer 141 and the second sub N-type layer 142 and any additional sub N-type layers, if present. In an embodiment, the N-type layer 140 is a product of the first sub N-type layer 141 and the second sub N-type layer 142. In an embodiment, the N-type layer 140 may have a thickness of about 0.1 to about 40 μm, specifically about 1 to 20 μm, more specifically about 2 to about 10 μm. Thus in an embodiment, the N-type layer 140 is formed by repeating a process of forming each sub N-type layer.

Next, as shown in FIG. 1, a second electrode 150 is disposed by depositing a transparent conductive metal such as ZnO, ITO, or IZO on the N-type layer 140, thereby forming a solar cell 100.

Although the first electrode 120 comprises a reflective conductive metal and the second electrode 150 comprises a transparent conductive metal in the foregoing embodiment, the first electrode 120 may comprise a transparent conductive metal and the second electrode 150 may comprise a reflective conductive metal.

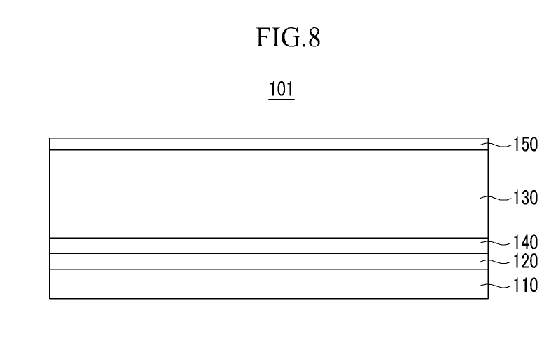

Next, a solar cell according to another embodiment will be further disclosed with reference to FIGS. 8 to 12.

FIG. 8 is a cross-sectional view of a solar cell according to another exemplary embodiment.

As shown in FIG. 8, in a solar cell 101, the positions of a P-type layer 130 and an N-type layer 140 are different than in the solar cell 100, and the P-type layer 130 is a light absorbing layer, as compared to the solar cell 100 according to the exemplary embodiment of FIG. 1.

The solar cell 101 includes a first electrode 120 disposed on a substrate 110. The first electrode 120 comprises a reflective conductive metal such as molybdenum (Mo), aluminum (Al), or copper (Cu). Also, the first electrode 120 may comprise a transparent conductive metal such as ZnO, indium tin oxide (“ITO”), or indium zinc oxide (“IZO”). A combination comprising at least one of the foregoing can be used.

On the first electrode 120, an N-type layer 140 and a P-type layer 130 are sequentially disposed.

The N-type layer 140 may be formed by doping amorphous silicon with an N-type impurity, such as phosphorus (P), and may have a thickness of about 0.1 to about 10 μm, specifically about 0.2 to about 5 μm, more specifically about 0.5 to about 1 μm. The P-type layer 130 may be formed by doping mirco-crystalline silicon with a P-type impurity such as boron (B), or aluminum (Al), and may have a thickness of about 0.1 to about 40 μm, specifically about 1 to 20 μm, more specifically about 2 to about 10 μm.

On the P-type layer 130, a second electrode 150 is disposed. The second electrode 150 may comprise a transparent conductive metal, such as ZnO, ITO, or IZO. Also, the second electrode 150 may comprise a reflective conductive metal such as molybdenum (Mo), aluminum (Al), or copper (Cu). A combination comprising at least one of the foregoing can be used.

In an embodiment, if the first electrode 120 comprises a reflective conductive metal, the second electrode 150 may comprise a transparent conductive metal, and if the first electrode 120 comprises a transparent conductive metal, the second electrode 150 may comprise a reflective conductive metal.

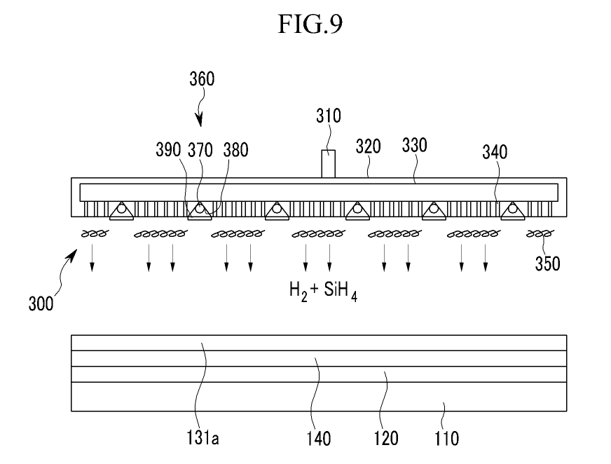

Next, a method of manufacturing a solar cell according to another exemplary embodiment will be further disclosed with reference to FIGS. 9 to 12.

FIGS. 9 to 12 are views sequentially showing an embodiment of a method of manufacturing a solar cell.

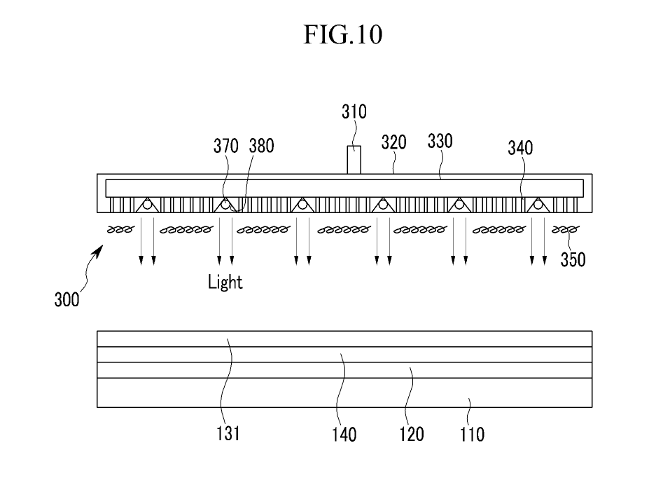

First, as shown in FIGS. 9 and 10, on a substrate 110, a first electrode 120 is disposed by depositing a reflective conductive metal, such as molybdenum (Mo), aluminum (Al), or copper (Cu), and on the first electrode 120, an N-type layer 140 is formed by doping amorphous silicon with an N-type impurity, such as phosphorus (P). In an embodiment, the N-type layer 140 may have thickness of about 0.01 to about 10 μm, specifically about 0.05 to about 5 μm, more specifically about 0.1 to about 0.5 μm.

Next, a second amorphous silicon layer 131a is formed on the N-type layer 140 using the crystalline silicon manufacturing apparatus 300. The gas, which comprises monosilane (SiH₄) and hydrogen (H₂), is injected into the body 320 of the crystalline silicon manufacturing apparatus 300, is diffused by the diffusion unit 330, and is jetted by the gas jetting units 340, and the jetted gas is decomposed or activated by the at least one hot wire 350, whereby the second amorphous silicon layer 131a is formed.

Next, the covers 390 of the lamp units 360 are removed and light is irradiated onto the second amorphous silicon layer 131a, whereby the second amorphous silicon layer 131a is crystallized so as to form a first sub P-type layer 131. In an embodiment, the first sub P-type layer 131 may have a thickness of about 0.01 to about 10 μm, specifically about 0.05 to about 5 μm, more specifically about 0.1 to about 0.5 μm.

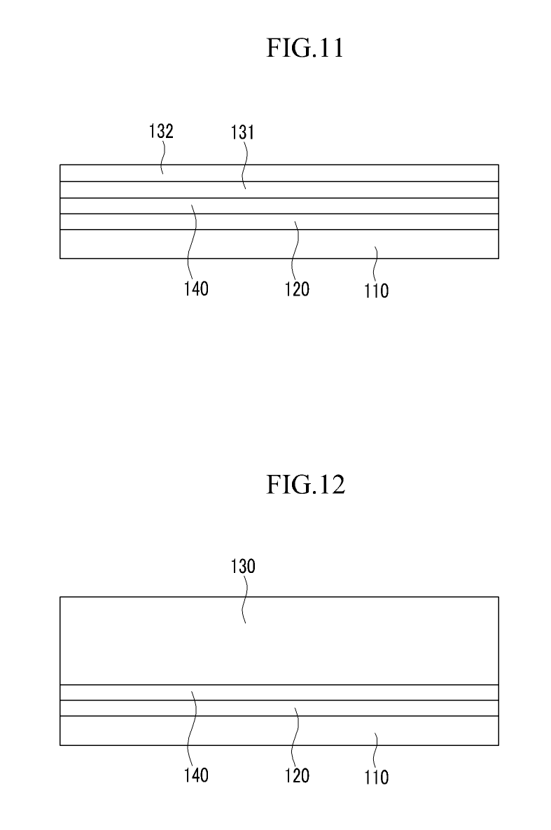

Next, as shown in FIGS. 11 and 12, a second sub P-type layer 132 is formed on the first sub P-type layer 131. The second sub P-type layer 132 is formed by the same method as the method of forming the first sub P-type layer 131. That is, an amorphous silicon layer is formed and crystallized on the first sub P-type layer 131 using the crystalline silicon manufacturing apparatus 300, so as to form the second sub P-type layer 132. The second sub P-type layer 132 may have the same or a different thickness as the thickness of the first sub P-type layer 131, and may have a thickness of about 0.01 to about 10 μm, specifically about 0.05 to about 5 μm, more specifically about 0.1 to about 0.5 μm.

Then, a P-type layer 130 is formed on the N-type layer 140 by repeating the mirco-crystalline silicon forming process many times using the crystalline silicon manufacturing apparatus 300. The P-type layer 130 may thus comprise a product of the first sub P-type layer 131 and the second sub P-type layer 132, and any additional sub P-type layers, if present. In an embodiment, the P-type layer 130 is a product of the first sub P-type layer 131 and the second sub P-type layer 132. In an embodiment, the P-type layer 130 may have a thickness of about 0.1 to about 40 μm, specifically about 1 to about 20 μm, more specifically about 2 to about 10 μm. That is, the P-type layer 130 is formed by repeating the process for forming each sub P-type layer.

Next, as shown in FIG. 8, a second electrode 150 is disposed by depositing a transparent conductive metal, such as ZnO, ITO, or IZO on the P-type layer 130, thereby forming the solar cell 101.

Although the first electrode 120 comprises a reflective conductive metal and the second electrode 150 comprises a transparent conductive metal in the foregoing embodiment, the first electrode 120 may comprise a transparent conductive metal and the second electrode 150 may comprise a reflective conductive metal.

As further described above, in a single apparatus, a gas comprising monosilane (SiH₄) and hydrogen (H₂) can be decomposed or activated with a hot wire so as to form an amorphous silicon layer, and then light can be irradiated onto the amorphous silicon layer to crystallize the amorphous silicon layer, thereby forming a high-quality mirco-crystalline silicon layer. Further, it is possible to solve substrate deformation and impurity diffusion problems by repeatedly forming thin mirco-crystalline silicon layers.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a solar cell, the method comprising:
forming a first electrode on a substrate;
forming a P-type layer on the first electrode;
forming an N-type layer on the P-type layer using a crystalline silicon manufacturing apparatus; and
forming a second electrode on the N-type layer to form the solar cell,
wherein the forming of the N-type layer comprises
contacting the P-type layer with a gas comprising monosilane and hydrogen to form a sub N-type layer comprising an amorphous silicon layer,
mirco-crystallizing the amorphous silicon layer by irradiating light onto the amorphous silicon layer, and
repeating the contacting and the mirco-crystallizing to form the N-type layer.

2. The method of claim 1, wherein a thickness of each sub N-type layer is independently about 0.1 to about 0.5 micrometer.

3. The method of claim 2, wherein a thickness of the N-type layer is about 1 to about 20 micrometers.

4. The method of claim 3, wherein a thickness of the P-type layer is about 0.1 to about 0.5 micrometer.

5. The method of claim 1, wherein the crystalline silicon manufacturing apparatus comprises:
a body,
a gas inlet, which is fluidly connected to the body,
a plurality of gas jetting units, which jet the gas,
at least one hot wire, which is separated from each gas jetting unit of the plurality of the gas jetting units and which decomposes or activates the jetted gas, and
a plurality of lamp units, wherein each lamp unit of the plurality of lamp units is disposed between respective the gas jetting units of the plurality of gas jetting units and wherein each lamp unit of the plurality of lamp units irradiates light onto the amorphous silicon layer.

6. The method of claim 5, wherein the at least one hot wire is disposed at only at portions corresponding to the gas jetting units.

7. The method of claim 6, wherein each lamp unit of the plurality of lamp units comprises:
a lamp, which emits light,
a reflective film, which reflects the emitted light, and
a cover, which protects the lamp and the reflective film, and
wherein the method of manufacturing the solar cell further comprises:
removing the cover; and then
irradiating light onto the amorphous silicon layer.

8. The method of claim 1, wherein the crystalline silicon manufacturing apparatus comprises:
a plurality of gas jetting units, which jet the gas,
at least one hot wire, which is separated from each gas jetting unit of the plurality of gas jetting units and which decomposes or activates the gas, and
a plurality of lamp units, each of which is disposed between respective gas jetting units of the plurality of gas jetting units and which irradiate light onto the amorphous silicon layer.

9. The method of claim 8, wherein the at least one hot wire is disposed only at a portion corresponding to the gas jetting units.

10. The method of claim 9, wherein each lamp unit of the plurality of lamp units further includes a cover, and
wherein the method of manufacturing the solar cell further comprises:
removing the cover, and then
irradiating light onto the amorphous silicon layer.

11. The method of claim 1, wherein the gas comprises monosilane and hydrogen.

12. A method of manufacturing a solar cell, comprising:
forming a first electrode on a substrate;
forming an N-type layer on the first electrode;
forming a P-type layer on the N-type layer using a crystalline silicon manufacturing apparatus; and
forming a second electrode on the P-type layer to form the solar cell,
wherein the forming of the P-type layer comprises
contacting the N-type layer with a gas comprising monosilane and hydrogen to form a sub P-type layer comprising an amorphous silicon layer,
mirco-crystallizing the amorphous silicon layer by irradiating light onto the amorphous silicon layer, and
repeating the contacting and mirco-crystallizing to form the P-type layer.

13. The method of claim 12, wherein a thickness of each sub P-type layer is independently about 0.1 to about 0.5 micrometer.

14. The method of claim 13, wherein a thickness of the P-type layer is about 1 to about 20 micrometers.

15. The method of claim 14, wherein a thickness of the N-type layer is about 0.1 to about 0.5 micrometer.

16. A crystalline silicon manufacturing apparatus comprising:
a body;
a gas inlet, which fluidly connected to the body;
a plurality of gas jetting units, which jet a gas comprising monosilane and hydrogen;
at least one hot wire, which is separated from each gas jetting unit of the plurality of the gas jetting units and which decomposes or activates the jetted gas; and
a plurality of lamp units, wherein each lamp unit of the plurality of lamp units is disposed between respective gas jetting units of the plurality of gas jetting units and wherein each lamp unit of the plurality of lamp units irradiates light.

17. The apparatus of claim 16, wherein the at least one hot wire is disposed only at a portion corresponding to the gas jetting units.

18. The apparatus of claim 16, wherein each lamp unit of the plurality of lamp units comprises:
a lamp, which emits light,
a reflective film, which reflects the emitted light, and
a cover, which protects the lamp and the reflective film.

19. The apparatus of claim 18, wherein the body comprises a diffusion unit, which diffuses the gas.
